(19) United States
(12) Patent Application Publication
(10) Pub. No.: US 2007/0148890 A1
(43) Pub. Date: Jun. 28, 2007

(54) Oxygen enhanced metastable silicon germanium film layer

(76) Inventors: Darwin G. Enicks, Colorado Springs, CO (US); John T. Chaffee, Colorado Springs, CO (US); Damian A. Carver, Colorado Springs, CO (US)

Correspondence Address: SCHNECK & SCHNECK, P.O. BOX 2-E, SAN JOSE, CA, 95109-0005, US

(21) Appl. No.: 11/318,797

(22) Filed: Dec. 27, 2005

(51) Int. Cl. H01L 21/331

(52) U.S. Cl. 438/312; 438/317; 438/372

(57) ABSTRACT

A method for pseudomorphic growth and integration of a strain-compensated metastable and/or unstable compound base having incorporated oxygen and an electronic device incorporating the base is described. The strain-compensated base is doped by substitutional and/or interstitial placement of a strain-compensating atomic species. The electronic device may be, for example, a SiGe NPN HBT.

### TECHNICAL FIELD

The invention generally relates to methods of fabrication of integrated circuits (ICs). More specifically, the invention is a method of fabricating and integrating a metastable silicon germanium (SiGe) base region into an electronic device such as a SiGe heterojunction bipolar transistor (HBT).

### BACKGROUND AND RELATED ART

The SiGe HBT has significant advantages over a silicon (Si) bipolar junction transistor (BJT) in characteristics such as gain, frequency response, and noise parameters. Further, the SiGe HBT retains an ability to integrate with CMOS devices at relatively low cost. Cutoff frequencies, Fₜ, of SiGe HBT devices have been reported to exceed 300 GHz, which compares favorably with gallium-arsenide (GaAs) devices. However, GaAs devices are relatively high in cost and cannot achieve a level of integration, such as can be achieved with BiCMOS devices. A silicon compatible SiGe HBT provides a low cost, high speed, low power solution that is quickly replacing other compound semiconductor devices.

Advantages of SiGe are realized partially due to an enhanced capability for bandgap engineering due to an addition of Ge to a Si lattice. For instance, an energy band offset at the Si—SiGe heterojunction of the HBT results in increased current densities and lower base current for a given base-emitter bias, equating to higher gains. Also, a lower resistivity is possible with addition of Ge to the Si lattice. The higher current densities and lower base resistance values allow improved unity gain cutoff frequencies and maximum oscillation frequencies than comparable silicon BJTs, and are comparable to other compound devices such as GaAs. However, the emitter collector breakdown voltage (especially BVCE0) is inversely proportional to the current gain (β). The structural and process changes required to enhance cutoff frequencies and reduce power lead to increasingly higher current gains and hence decreasingly lower collector-emitter breakdown voltages.

Elevated Ge fractions result in an increase in base recombination current and a reduction in current gain for a given layer thickness and doping level. The base recombination current increase/current gain reduction effect has been confirmed experimentally to extend beyond 30% Ge. References on defect formation in pseudomorphic SiGe with high Ge content suggest the effect will continue to increase for Ge fractions well above 40% (i.e., Kasper et al., “Properties of Silicon Germanium and SiGe:Carbon”, INSPEC, 2000). Therefore, a compromise of increasing Ge fraction high enough to reduce current gain in high-speed devices provides a way to compensate for an inevitable increase in gain and degradation of BVCEO as base-widths continue to shrink.

However, there is a limit to how much Ge can be added to the Si lattice before excess strain relaxation and gross crystalline defects occur. A critical thickness, h_{c} of a SiGe layer that is lattice matched to underlying silicon is primarily a function of (1) percentage of Ge employed; (2) SiGe film thickness; (3) a thickness of a cap layer; (4) temperature of HBT film-stack processing; and, (5) temperature of thermal anneals following a SiGe deposition. Above the critical thickness, h_{c}, the SiGe film is in a metastable and/or unstable region which implies it will relax readily with a large enough application of thermal energy. Therefore, a degree of metastability is largely a function of percent Ge, SiGe layer thickness, cap layer thickness, and process induced strain due to thermal energy. Construction of a SiGe base of a conventional SiGe HBT described to date is that of a stable pseudomorphic or lattice-matched layer. Contemporaneous state-of-the-art procedures include growing stable, strained, or lattice-matched alloys of SiGe with carbon to prevent spreading of a boron concentration-profile in the base region.

Metastable film growth is typically avoided due to the fact that relaxation results in lattice imperfections. These imperfections result in recombination centers; hence, a reduction in minority carrier lifetime, τ_{b} and an increase in base recombination current, I_{RB}, occurs. If not controlled, a resultant poor crystal quality due to lattice imperfections will degrade device performance. Bridging defects will also lead to excessive leakage current along with extremely low current gain. The film will also be very sensitive to process induced thermal stresses and therefore will not be manufacturable. Therefore, to avoid this type of degradation, the HBT designs to date result in a device with a base region that is in the stable region of film growth which equates to a SiGe thickness that is equal to or below the critical thickness, h_{c}.

It is known that oxygen will reduce dislocation velocities of metastable films by an order of magnitude. Therefore oxygen incorporation into the crystalline lattice is beneficial in delaying an onset of undesirable relaxation effects in high-percentage Ge films (See D. C. Houghton, “Strain relaxation kinetics in Si₁₋ₓGeₓ/Si heterostructures,” J. Appl. Phys., 70 (4), p. 2142 (Aug. 15, 1991)). It is also known that oxygen will reduce boron diffusion much the same as carbon (See D. Knoll et al., “Influence of the Oxygen Content in SiGe on Parameters of Si/SiGe Heterojunction Bipolar Transistors,” Journal of Electronic Materials, Vol. 27, No. 9 (1998)). Therefore, there are multiple benefits with controlled oxygen incorporation. In fact, the intentional addition of oxygen to the SiGe lattice represents a radical departure from contemporary mainstream technologies and may have significant importance for the near future.

Further, carbon incorporated into SiGe films, in addition to reducing boron diffusion, will assist in compensating compressive strain in pseudomorphic SiGe by reducing an average lattice parameter relative to the Si. However, carbon also outdiffuses rapidly during thermal anneals, which follow the growth of strained silicon germanium carbon films.

To achieve even greater energy band offsets, ΔEv, it is therefore necessary to integrate even more Ge. However, an upper limit of the metastable regime places a constraint on SiGe processing and device design as partially detailed supra. As the upper limit is approached, crystalline defect propagation is greatly enhanced with an accelerated relaxation of the strained SiGe film.

Therefore, what is needed is a method to grow and integrate strain-compensated metastable (or unstable) SiGe with a method for terminating crystalline defects to inhibit or delay their propagation, thereby effectively allowing film growth in the metastable region with ever-greater concentrations of Ge. Such a method should allow an engineer to control an amount of metastability of the SiGe to achieve advantages offered with high concentrations of Ge and yet allow optimization of current density, current gain, breakdown voltages, cutoff frequencies, and maximum frequency.

### SUMMARY OF THE INVENTION

The present invention is a method for pseudomorphic growth and integration of a strain-compensated metastable and/or unstable compound base. The strain-compensated base may be in-situ doped by substitutional and/or interstitial placement of a strain-compensating atomic species.

In one exemplary embodiment, the present invention is a method for fabricating a compound semiconductor film. The method includes providing a substrate such as, for example, a silicon wafer. A compound semiconductor film (e.g., SiGe) having a substantially crystalline lattice structure is formed over a first surface of the substrate. The compound semiconductor is in a metastable state with oxygen incorporated into the crystalline lattice structure. The compound semiconductor film is further doped with a strain-compensating atomic species such as carbon.

The present invention is also an electronic device having a compound semiconductor film disposed over a first surface of a substrate. Assuming, for example, a SiGe compound semiconductor film, the compound semiconductor film includes a substantially crystalline silicon lattice structure with incorporated oxygen and a high concentration of an additional semiconducting material (e.g., such as a high-percentage of germanium incorporated into the SiGe lattice) such that the compound semiconductor film is in a metastable state. Additionally, a strain-compensating atomic species is substitutionally doped into the compound semiconductor.

### BRIEF DESCRIPTION OF THE DRAWINGS

FIG. 1 is an exemplary film stack 100 used in forming a strain-compensated metastable base layer of a heterojunction bipolar transistor (HBT).

FIG. 2 is an exemplary graph for determining critical thickness of a strain-compensated metastable SiGe base region as a function of germanium content.

FIGS. 3 and 4 are x-ray diffraction rocking curves.

FIGS. 5-7 are various germanium concentration profiles which may be used in an HBT device.

### DETAILED DESCRIPTION

A strain-compensating atomic species is an element having an atomic radius different than a radius of elements making up the strained crystalline lattice. For strain-compensation of SiGe, a preferred compensating species is carbon. A skilled artisan will recognize that a level of 1% of substitutional carbon will compensate 8% to 10% of Ge. Carbon can be substitutionally placed to a level of approximately 2.5% in SiGe, or enough carbon to strain-compensate 20% to 25% of Ge. Strain-compensated metastable films having Ge levels of greater than 40% are possible for use in electronic devices. Details for metastable film determination are discussed in more detail infra.

The present invention outlined herein differs significantly from contemporary usage of metastable films. Here, oxygen is intentionally added to a SiGe lattice to assist in terminating crystalline defect propagation, thus allowing even higher Ge incorporation and the associated benefits discussed supra.

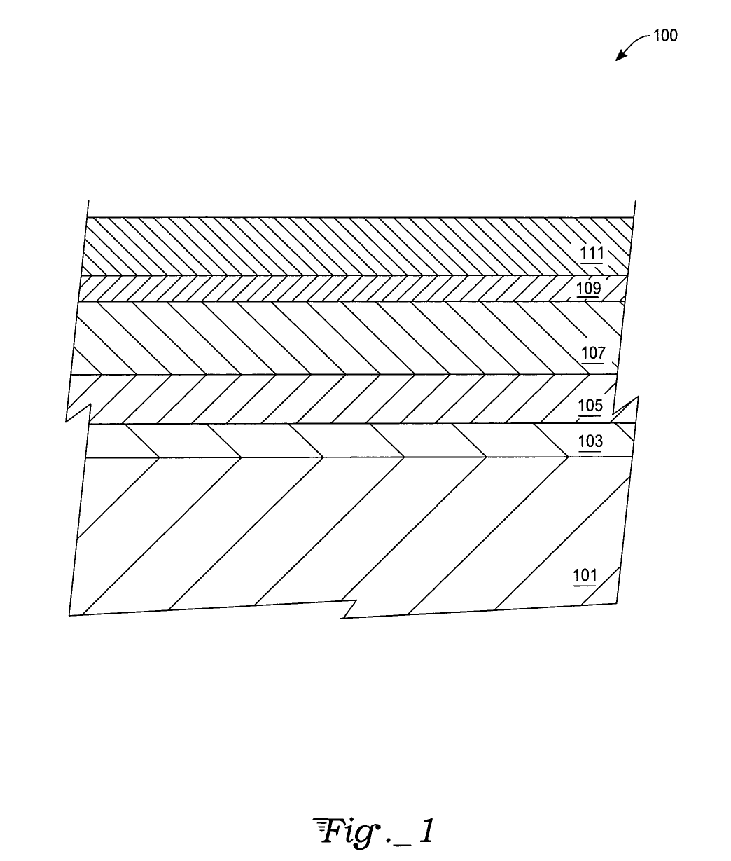

With reference to FIG. 1, an exemplary film stack 100 used in forming a strain-compensated metastable base layer of an HBT includes a substrate 101, an epitaxial layer 103, an elemental seed layer 105, a strain-compensated metastable (or unstable) SiGe base region 107, an elemental cap layer 109, and a polysilicon emitter layer 111. (One skilled in the art will recognize that other materials may be employed for the emitter layer 111 such as, for example, polySiGe.)

In a specific exemplary embodiment, the substrate 101 is a p-type, 20 Ω-cm <100> silicon wafer. The epitaxial layer 103 may be Silicon or SiGe, grown by low-pressure chemical vapor deposition (LPCVD) and can be either p-type or n-type depending on the technology application and the requirements for breakdown voltages and collector resistance. Arsenic and/or phosphorous may be doped into both the epitaxial layer 103 and the substrate 101 to provide a low resistance collector region. The arsenic and phosphorous may be diffused or implanted. If implanted, one skilled in the art will recognize that the energy and dose of the implant may be determined by specific technology requirements for characteristics such as collector resistance, breakdown voltages, and so on. A skilled artisan will also recognize that other methods may be employed to dope this region, such as diffusion or LPCVD (in-situ doping).

In the case of a silicon substrate 101, prior to growth, the silicon growth surface should be cleaned (e.g., with a wet chemistry such as hydrofluoric acid) to remove any native oxide and surface contaminants. After subsequent growth of the epitaxial layer 103, the elemental seed layer 105, the metastable base region 107, and the elemental cap layer 109 may be fabricated sequentially during an LPCVD process. Temperatures in a range of 500° C. to 900° C. are typically employed for epitaxial growth of each layer. Silane (SiH₄) and germane (GeH₄) are typical gases for silicon and SiGe deposition. Diborane (B₂H₆) and arsine (AsH₃) are common p- and n-type dopant sources. Hydrogen (H₂) may be utilized as a carrier gas, however other gases such as helium may be used.

In another specific exemplary embodiment, the substrate 101 is a <100> p-type silicon wafer, boron doped to a concentration of approximately 10¹⁵ atoms/cm³. Alternatively, the substrate 101 could also be, for example, an n-type silicon wafer or a substrate comprised of a compound semiconducting material such as silicon-germanium of either p-type or n-type conductivity. The substrate 101 may also be, for example, silicon-on-insulator (SOI) or silicon germanium-on-insulator. In this embodiment, the epitaxial layer 103 is added as a low-doped region to tailor breakdown voltages and/or collector resistance and is deposited to a thickness of between 0.3 μm and 2 μm, followed by growth or deposition of the elemental seed layer 105. The elemental seed layer 105 is comprised of silicon and is epitaxially grown to a thickness range of 10 nm to 100 nm. Alternatively, the epitaxial layer 103 may employ other semiconducting materials, such as silicon germanium with a low Ge content. The strain-compensated metastable SiGe layer 107 is deposited to a thickness greater than the critical thickness, h_{c}, followed by the elemental cap layer 109 comprised of, for example, silicon. The critical thickness, h_{c}, of the strain-compensated metastable SiGe base region 107 is determined based on atomic percentage of Ge within an upper and lower bound of a metastable region. The critical thickness determination is based on historical work of People/Bean and Matthews/Blakeslee, and is known to one of skill in the art.

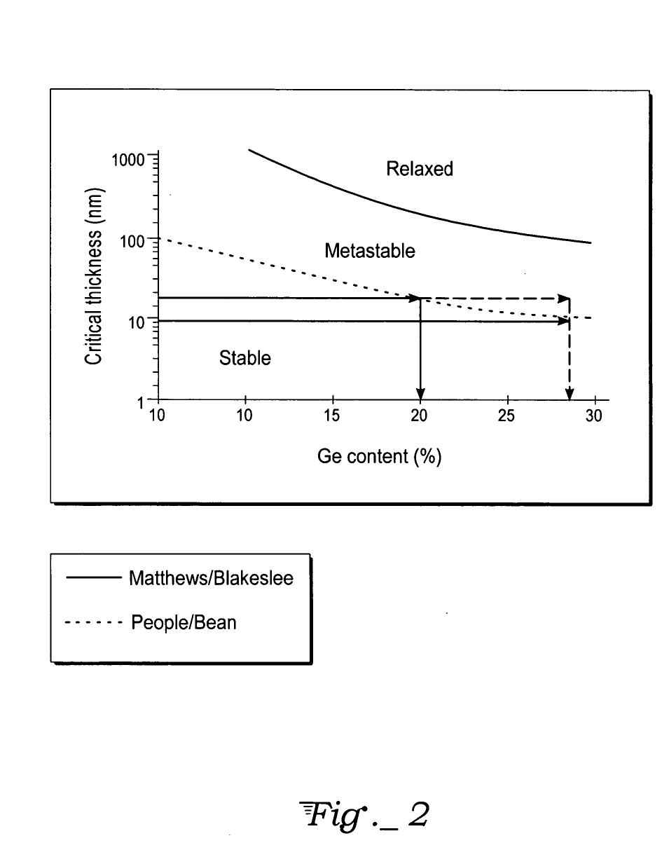

As an example, FIG. 2 shows that for a film with 20% Ge, the critical thickness, h_{c}, according to the People/Bean curve as defined by the bottom edge of the metastable region and is approximately 20 nm, while a film with 28% Ge has a critical thickness, h_{c}, of only 9 nm. Therefore, to grow a fully “strain compensated” film with 28% Ge that is also 20 nm thick, carbon may be added to reduce the lattice parameter and strain compensate 8% of Ge. The addition of 1% of carbon throughout the SiGe lattice of a 20 nm, 28% Ge film will reduce the strain to a level that approximates that of a 20 nm, 20% Ge film. However, one skilled in the art will recognize that it might be technologically desirable to provide only enough carbon to partially strain compensate, for example, by adding 0.5% carbon for purposes of defect engineering. Alternatively, 2% carbon may be added for purposes of adding thermal processing robustness.

Additionally, one may desire to grow a film that resides well into the metastable region, and then to only partially compensate the film thereby maintaining a certain degree of metastability for defect and/or lattice engineering.

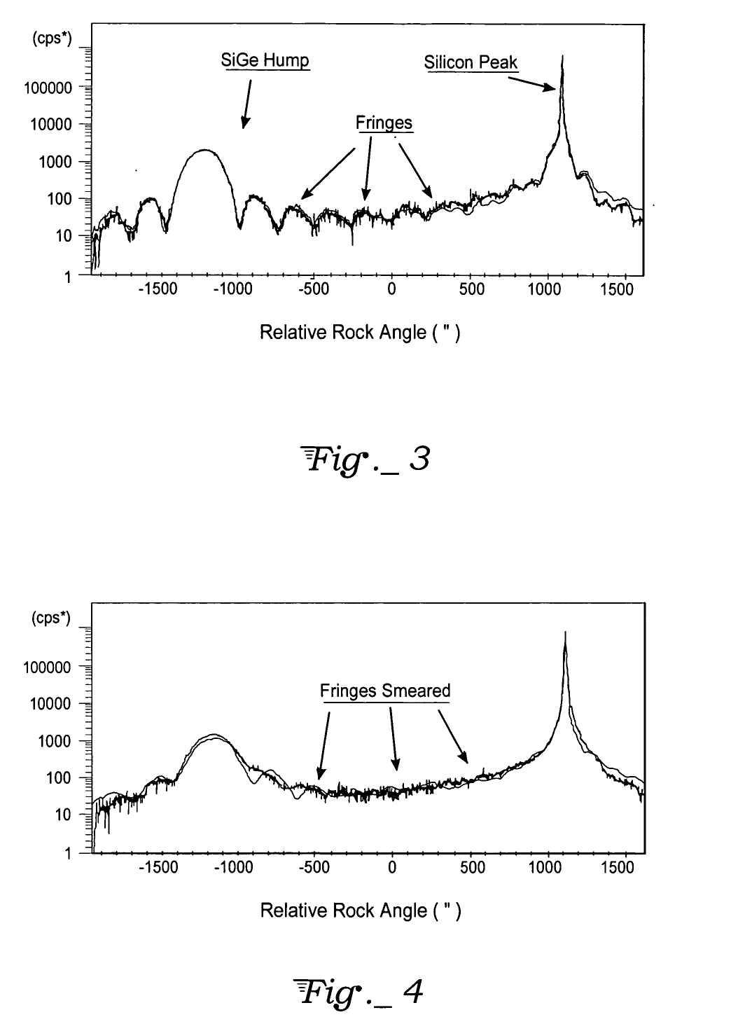

One skilled in the art will recognize that data and charts such as those of FIG. 2 are meant to provide approximations, but that other means, such as x-ray diffraction (Xrd) rocking curves are necessary to assist in determining where an optimum degree of metastability resides for a certain film structure and/or device. With reference to FIG. 3, one skilled in the art will know that distinct “fringes” between a silicon peak and a “SiGe hump” are indicative of a lattice matched or strained layer.

The absence of and/or “smearing” of fringes in the Xrd rocking curves will indicate a film relaxation as indicated by FIG. 4 following a thermal anneal cycle. One skilled in the art will also know that Xrd rocking curves assessed following film growth and also following any downstream thermal treatments will provide information necessary for tailoring of the strain compensation process and/or thermal processes to avoid complete strain or lattice relaxation for optimal oxygen incorporation.

One skilled in the art will recognize that, in addition to Xrd rocking curves, secondary-ion mass spectrometry (SIMS) can provide metrology and simulation tools required to properly incorporate oxygen, and consequently determine a degree of strain and/or relaxation of the film following growth before and after any downstream thermal (e.g., annealing) operations. A skilled artisan will further recognize that an amount of oxygen to incorporate and mitigate defect propagation may be tailored to achieve desired film parameters such as sheet resistance, and also device parameters such as current gain, cutoff frequency, leakage current, and so on. Optimum tailoring for oxygen incorporation (i.e., to determine an optimum Ge to oxygen ratio within the strain-compensated metastable SiGe base region 107) may be determined by various statistical design-of-experiments (DOE) to determine an optimum Ge to oxygen ratio within the film. Either SIMS or Xrd may be utilized to optimize the Ge to oxygen ratio. Comparison of the Xrd and SIMS for an undoped SiGe film (i.e., containing no oxygen) to Xrd and SIMS analysis of the film with oxygen provides the necessary information. Additionally, device electrical tests provide experimental data necessary to determine an effect of oxygen on base recombination and, hence, current gain and breakdown. Therefore, Xrd, SIMS, and electrical test data will aid in optimizing Ge and oxygen content.

Other experimental approaches may be utilized, such as putting electrical devices through electrical testing to identify the acceptable level of strain compensation for a particular device or technology. This acceptable level will be determined by device electrical parameters, especially the collector current, base current, current gain, and breakdown voltages for an HBT. Other electrical parameters may be characterized and controlled for other device types and/or technologies. With reference again to FIG. 1, an oxygen precursor is utilized during growth of the elemental seed layer 105 and the strain-compensated metastable SiGe layer 107. Oxygen (for example, heliox He0), coupled with silane (SiH₄) and germane (GeH₄) are frequently-used silicon and germanium precursors, which may be used for forming the elemental seed layer 105 and the strain-compensated metastable SiGe layer 107, respectively. For example, a p-type neutral base region may be created by in-situ doping of a thin section near the center of the strain-compensated metastable SiGe layer 107. The neutral base region is sandwiched between two SiGe setback or spacer layers. The SiGe setback or spacer layers are typically undoped SiGe layers which allow room for boron dopant diffusion and prevent a formation of metallurgical junctions that are outside of the Si/SiGe heterojunctions. The boron doped SiGe layer is sandwiched between the SiGe spacer layers. Alternatively, the emitter-base spacer or setback layer may be doped with an n-type dopant (described in more detail, infra).

In a specific exemplary embodiment, the setback layer on the emitter-base side is doped with arsenic. The p-type impurity is boron and the precursor is diborane (B₂H₆). The elemental cap layer 109 is grown on top of the base region formed in the metastable SiGe layer 107. A profile of the concentration of Ge in silicon profile may be tailored to have a specific profile.

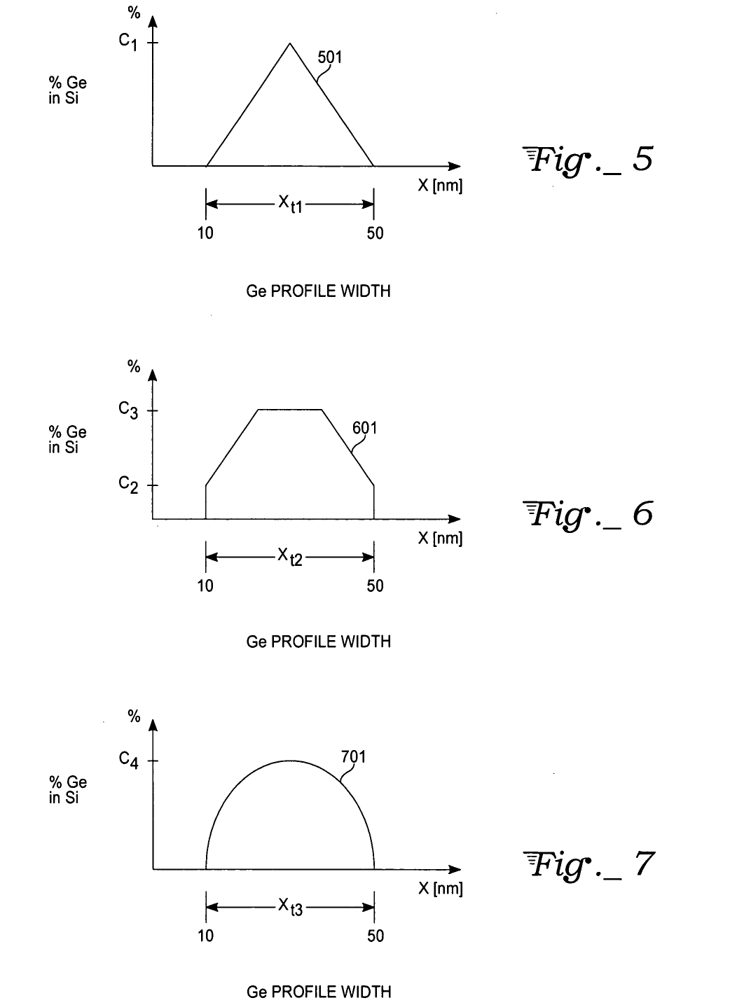

With reference to FIG. 5, a triangular germanium concentration profile 501 of an HBT device in a particular embodiment indicates a Ge profile width, xₜ₁, of between 10 nm and 50 nm. A maximum concentration, C₁, of germanium in the approximate center of the dopant layer is between 0.1% and 100%. The triangular germanium concentration profile 501 allows very high early voltages. Moreover, the triangular germanium concentration profile 501 creates a drift field for reducing a base transit time of minority carriers.

An HBT device with a trapezoidal germanium concentration profile 601 of FIG. 6 also has a Ge profile width, xₜ₂, of between approximately 10 nm and 50 nm. The concentration of germanium in the base layer increases linearly from a side of the collector or emitter of the transistor from about 5% at level C₂ approaching 100% at C₃. In this embodiment, high current gain as well as high early voltage and a drift field are attained, thus reducing base transit time.

A semicircular concentration profile 701 of FIG. 7 has a Ge profile width, xₜ₃, of between approximately 10 nm and 50 nm. The concentration of germanium increases in, for example, a semicircular or parabolic manner to a maximum concentration as high as 100% at C₄. One skilled in the art will recognize that other germanium concentration profiles are possible as well.

With reference again to FIG. 1, the polysilicon emitter layer 111 is formed over the elemental cap layer 109. The polysilicon emitter layer 111 is commonly doped with an n-type dopant; for example, doping may occur with arsenic by a precursor of arsine (AsH₃) gas. Hydrogen is frequently a carrier gas for this process. Typically, SiGe deposition temperatures are in a 500° C. to 650° C. range. In this embodiment, a growth temperature is below 600° C., and a processing pressure can be controlled from 1 torr to 100 torr.

Additionally, a final location of incorporated oxygen will affect device characteristics. Oxygen may be placed at any given location with the film layer(s) depending on the type of device application and the requirements of the technology. For example, oxygen may be placed throughout all SiGe layers in a predetermined quantity to both inhibit boron diffusion and to mitigate formation of gliding defects within the lattice. The oxygen will also increase base recombination due to electrically active defects within the neutral base region, therefore reducing current gain, and increasing the BVCE0. Alternatively, oxygen may be placed only in the spacer or setback layer(s) in a predetermined quantity, but not in the neutral base region (boron doped region). This placement will assist with mitigating gliding defects and allow higher Ge incorporation, but will minimize the oxygen effect on recombination current in the neutral base (i.e., no oxygen in the boron doped layer), thus allowing for higher current gains depending upon device requirements. Due to the selectability of location and quantity, device parameters such as base recombination, current gain, and breakdowns can be tailored to meet specific device performance requirements.

Although the present invention is described in terms of exemplary embodiments, a skilled artisan will realize that techniques described herein can readily be adapted to other forms of fabrication techniques and devices. For example, the strain-compensation techniques could be applied to other technologies such as FinFET, surround gate FET, vertical thin film transistors (VTFT), hyper-abrupt junctions, resonant tunnel diodes (RTD), and optical waveguides for photonics. Therefore, profiles, thicknesses, and concentrations of the strain-compensated metastable SiGe layer 107 can be selected to accommodate a variety of needs. The metastable SiGe layer 107 could also be strain-compensated with other elements, which may induce a diminished diffusivity for a given dopant type.

Also, although exemplary process steps and techniques are described in detail, a skilled artisan will recognize that other techniques and methods may be utilized, which are still included within a scope of the appended claims. For example, there are several techniques used for depositing and doping a film layer (e.g., chemical vapor deposition, plasma-enhanced chemical vapor deposition, molecular beam epitaxy, atomic layer deposition, etc.). Although not all techniques are amenable to all film types described herein, one skilled in the art will recognize that multiple and alternative methods may be utilized for depositing or otherwise forming a given layer and/or film type.

Additionally, many industries allied with the semiconductor industry could make use of the strain-compensation technique. For example, a thin-film head (TFH) process in the data storage industry, an active matrix liquid crystal display (AMLCD) in the flat panel display industry, or the micro-electromechanical (MEM) industry could readily make use of the processes and techniques described herein. The term “semiconductor” should thus be recognized as including the aforementioned and related industries. The drawing and specification are, accordingly, to be regarded in an illustrative rather than a restrictive sense.

What is claimed is:

1. A method for fabricating a compound semiconductor film, the method comprising:
providing a substrate, the substrate having a first surface;
forming the compound semiconductor film over the first surface of the substrate, the compound semiconductor film having a substantially crystalline lattice structure, the compound semiconductor film further having a high concentration of a first semiconducting material of the compound semiconductor such that the compound semiconductor is in a metastable state;
incorporating oxygen into the crystalline lattice structure; and
doping the compound semiconductor film with a strain-compensating atomic species.

2. The method of claim 1, further comprising selecting a concentration of the strain-compensating species to control a defect density and enhance bandgap or lattice characteristics.

3. The method of claim 1 wherein the compound semiconductor is selected to be silicon germanium.

4. The method of claim 3 wherein the first semiconducting material of the selected compound semiconductor is comprised substantially of germanium.

5. The method of claim 1 wherein the strain-compensating species is selected to be carbon.

6. The method of claim 1 wherein the strain-compensating species is selected to reduce a lattice strain of the compound semiconductor.

7. The method of claim 1 wherein the strain-compensating species is selected to increase a lattice strain of the compound semiconductor.

8. The method of claim 1 wherein the step of doping the compound semiconductor film with the strain-compensating atomic species is performed in-situ.

9. The method of claim 1 further comprising profiling the first semiconducting material to have a trapezoidal shape.

10. The method of claim 1 further comprising profiling the first semiconducting material to have a triangular shape.

11. The method of claim 1 further comprising profiling the first semiconducting material to have a semicircular shape.

12. The method of claim 1 wherein the step of formation of the compound semiconductor occurs at a temperature in a range of 500° C. to 900° C.

13. The method of claim 1 wherein the step of formation of the compound semiconductor occurs at a temperature of less than 600° C.

14. The method of claim 1 further comprising forming the compound semiconductor film to a thickness greater than a critical thickness, h_{c}.

15. An electronic device comprising:
a substrate;
a compound semiconductor film disposed over a first surface of the substrate, the compound semiconductor film having a substantially crystalline lattice structure with incorporated oxygen, the compound semiconductor film further having a high concentration of a first semiconducting material of the compound semiconductor such that the compound semiconductor film is in a metastable state; and
a strain-compensating atomic species doped substitutionally into the compound semiconductor.

16. The electronic device of claim 15 wherein the compound semiconductor is comprised substantially of silicon germanium.

17. The electronic device of claim 16 wherein the first semiconducting material of the compound semiconductor is comprised substantially of germanium.

18. The electronic device of claim 15 wherein the strain-compensating species is carbon.

19. A method for fabricating a heterojunction bipolar transistor, the method comprising:
providing a substrate, the substrate having a first surface;
forming a silicon-germanium film over the first surface of the substrate, the silicon germanium film being formed to be in a metastable state;
incorporating oxygen into a substantially crystalline lattice structure of the silicon-germanium film; and
doping the silicon-germanium semiconductor film with a strain-compensating atomic species, the strain-compensating atomic species selected to be carbon.

20. The method of claim 19 further comprising tailoring the first semiconducting material to have a trapezoidal concentration profile shape.

21. The method of claim 19 further comprising tailoring the first semiconducting material to have a triangular concentration profile shape.

22. The method of claim 19 further comprising tailoring the first semiconducting material to have a semicircular concentration profile shape.

23. The method of claim 19 further comprising forming the compound semiconductor film to a thickness greater than a critical thickness, h_{c}.

24. A method for fabricating a compound semiconductor film, the method comprising:
providing a substrate, the substrate having a first surface;
forming the compound semiconductor film over the first surface of the substrate, the compound semiconductor film having a substantially crystalline lattice structure, the compound semiconductor film further having a high concentration of a first semiconducting material of the compound semiconductor such that the compound semiconductor is in an unstable state;
incorporating oxygen into the crystalline lattice structure; and
doping the compound semiconductor film with a strain-compensating atomic species.

25. The method of claim 24 wherein the compound semiconductor is selected to be silicon germanium.

26. The method of claim 25 wherein the first semiconducting material of the selected compound semiconductor is comprised substantially of germanium.

27. The method of claim 24 wherein the strain-compensating species is selected to be carbon.

28. The method of claim 24 wherein the strain-compensating species is selected to reduce a lattice strain of the compound semiconductor.

29. The method of claim 24 wherein the strain-compensating species is selected to increase a lattice strain of the compound semiconductor.
